(19) United States
(12) Patent Application Publication
(10) Pub. No.: US 2007/0209593 A1
(43) Pub. Date: Sep. 13, 2007

(54) Semiconductor wafer cooling device

(76) Inventors: Ravinder Aggarwal, Gilbert, AZ (US); Jim Kusbel, Scottsdale, AZ (US)

Correspondence Address: KNOBBE, MARTENS, OLSEN & BEAR LLP, 2040 MAIN STREET, FOURTEENTH FLOOR, IRVINE, CA, 92614, US

(21) Appl. No.: 11/369,773

(22) Filed: Mar. 7, 2006

(51) Int. Cl. H01L 21/677; C23C 16/00

(52) U.S. Cl. 118/724; 414/217

(57) ABSTRACT

This invention relates to an apparatus and a method for cooling a semiconductor wafer while it is being transferred from one station to another. More particularly, the invention relates to an active cooling system in the end effecter of a robot used for moving a semiconductor wafer from one process station to another.

### BACKGROUND OF THE INVENTION

1. Field of the Invention

This invention relates in certain embodiments to an apparatus and a method for cooling a semiconductor wafer while it is being transferred from one station to another. More particularly, in one embodiment the invention relates to an active cooling system in the end effecter of a robot used for moving a semiconductor wafer from one process station to another.

2. Description of the Related Art

Semiconductor wafers or other such substrates are subjected to very high processing temperatures. For example, in chemical vapor deposition (CVD), the temperatures may approach 1200° C. In a typical cycle, a wafer is transferred from a room temperature cassette by a robotic wafer handler into a reactor chamber where it is subjected to the high temperature processing and is then transferred by the wafer handler from the high temperature chamber back to the same cassette or a separate cassette for processed wafers. Because of the high temperature CVD processing, transport from the process chamber directly to a wafer cassette may not be possible due to the temperature of the wafer exceeding the material properties of most commonly used cassette materials.

The transfer of the wafer to a cassette may need to be postponed until the wafer temperature falls below a temperature allowed by the thermal properties of the cassette material. While cassettes are available that can handle wafers as hot as 170° C., they are relatively expensive. Commonly available units can only handle temperatures up to 70° C. If the cooling takes too long, it can have a direct impact on the system throughput. In some designs the loadlocks have limited capacities and a processed wafer must be removed before another wafer can be processed. In high throughput systems, it may mean that the wafer may have to be removed from the loadlock before it has cooled down to the temperature at which it can be placed on the cassette. Providing additional cool down steps and stations increases the number of handling sequences and the footprint of the system. Hence, it is desirable that the temperature of a wafer be quickly cooled without increasing the footprint and without decreasing throughput.

### SUMMARY OF THE INVENTION

In accordance with some embodiments of the invention, a wafer handling robot or robot arm is provided comprising a system on the end effector of the robot arm for cooling the wafer as it is moved from a loadlock chamber to a wafer input/output storage area. In this respect, the wafer is cooled while it is being moved, thus potentially increasing throughput without increasing the footprint of the wafer processing chamber, or the number of wafer handling steps.

In some embodiments, the robot arm with end effector cooling system can replace cooling stations that would otherwise be provided for cooling the wafers. In some embodiments, the robot arm with end effector cooling system can work in conjunction with a cooling station in order to free up the robot arm to move another wafer.

In some embodiments, two or more robotic arms are provided in order to increase throughput. For instance, while one robot arm, or one arm of a wafer-handling robot moves a wafer from the input storage area to the loadlock chamber, the other arm with an effector cooling system can move a hot wafer from the loadlock chamber to a cooling station or directly to an output storage area.

In some embodiments the cooling system connected to the robot arm comprises a system for conducting a fluid to the wafer in order to cool the wafer. The fluid may be routed through the body and arms of the robot, or it may be routed outside of the robot arm. The fluid may comprise any inert gas. In some embodiments, the fluid is Nitrogen gas.

The end effector cooling system can be configured to remove heat convectively or through conductive means. The fluid may be sprayed or otherwise conveyed directly onto the wafer. Or the fluid may circulate through an end effector, in direct contact with the wafer, thereby cooling the wafer. The fluid may also pass through an object, such as an end effector, which is not in direct contact, but is in close proximity to the wafer, thereby cooling the wafer indirectly without touching the wafer.

In one embodiment, a semiconductor processing device is provided comprising a wafer handling section connected to a first side of a loadlock chamber and including a wafer handling robot. A processing chamber communicates with the wafer handling section. A front end interface is connected to a second side of the loadlock chamber and includes a cassette rack. An interface robot may be located within the front end interface, which supports an end effector, and is configured to supply a fluid to a wafer held by the end effector. In some embodiments, the wafer handling section is an enclosed chamber.

In another embodiment, the semiconductor processing device comprises an interface robot which may be located within a front end interface for transporting semiconductor wafers between a loadlock chamber and a cassette rack. The front end interface may be connected to the loadlock chamber. A cassette rack may be provided which communicates with the front end interface. The interface robot may further comprise upper and lower fluid showerheads spaced apart from each other. The showerheads may be connected to a source of fluid to enable fluid to be projected through openings in the showerheads onto the upper and lower surfaces of a wafer in order to cool the wafer.

In another embodiment, a semiconductor processing device comprises a robot located within the front end interface capable of transporting wafers between a loadlock chamber and a cassette unit. The robot may comprise an end effector for holding a wafer. The front end interface may be connected to a loadlock chamber. The loadlock chamber may be configured to receive semiconductor wafers in a cassette unit.

In another embodiment, a semiconductor processing device may comprise a wafer handling chamber connected to a processing chamber. The wafer handling chamber may be configured to communicate with the loadlock chamber. The wafer handling chamber may also comprise a wafer handling robot configured to transport wafers from the processing chamber to the loadlock chamber.

In some embodiments, the semiconductor processing device may comprise a robot with an end effector for transporting wafers which may have passages through which cooling fluid is circulated. The cooling fluid is circulated so that the end effector will have a lower surface temperature after the fluid is circulated as compared to before the fluid is circulated. Cooling the end effector will have the result of cooling the wafer which the end effector is transporting. The robot may be located within the front end interface. The front end interface may be configured to receive semiconductor wafers in a cassette unit and may contain an end effector for transporting wafers from the loadlock chamber to the cassette unit. The front end interface may also be connected to the loadlock chamber

In another embodiment, a method of cooling a processed semiconductor wafer is provided comprising the steps of: moving a processed wafer from a loadlock chamber to an end effector of an interface robot; supplying a cooling fluid from the interface robot to the processed wafer; cooling the processed wafer to at least 70 degrees Celsius from a temperature above 71 degrees Celsius; and transporting the cooled wafer to a cassette rack with the interface robot. In some embodiments, the wafer may be processed at a temperature over 500 degrees Celsius prior to moving the processed wafer from the loadlock chamber to the end effector of the interface robot. In some embodiments, the wafer may be placed in cooling station in a wafer handling device prior to moving the processed wafer from the loadlock chamber to the end effector of the interface robot. In some embodiments, the starting temperature of the wafer while in the loadlock chamber and prior to moving into the wafer handling chamber is below 70 degrees Celsius.

### BRIEF DESCRIPTION OF THE DRAWINGS

FIG. 1 is a schematic plan view showing a section of a semiconductor process tool.

FIG. 2 is a schematic plan view showing an alternative embodiment of a semiconductor process tool.

FIG. 3 is a schematic plan view showing an alternative embodiment of a semiconductor process tool.

FIG. 4A is a schematic representation of a showerhead cooling system comprised in an end effector of a robot arm used for transporting wafers.

FIG. 4B is a schematic representation of a conductive cooling system comprised in an end effector of a robot arm used for transporting wafers.

FIG. 4C is a schematic representation of an alternative embodiments of a conductive cooling system comprised in an end effector of a robot arm used for transporting wafers.

FIG. 4D is a schematic representation of a Bernoulli wand cooling system comprised in an end effector of a robot arm used for transporting wafers.

FIG. 5 is a schematic view of a cooling system in an end effector.

FIG. 6 is a schematic view of an alternative embodiment of a cooling system in an end effector.

### DETAILED DESCRIPTION OF THE PREFERRED EMBODIMENTS

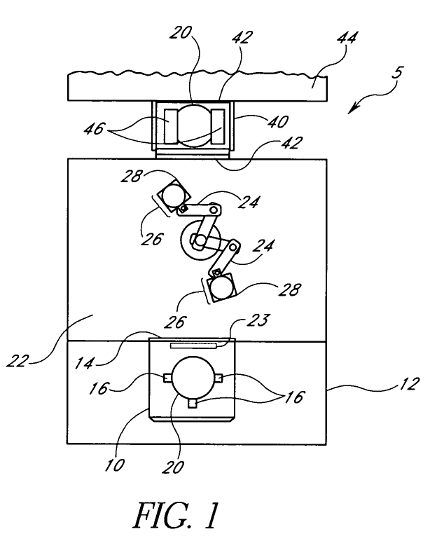

Referring now to FIG. 1, an overhead plan view shows a semiconductor process device 5. A cassette 10, preferably a front opening unified pod (FOUP), is located on a front end interface (FEI) loading platform 12, the cassette 10 being removably docked with docking port 14. Interior to the cassette 10 is a cassette rack 16 with individual slots (not shown), each slot capable of holding a wafer 20. The cassette 10 is joined with a FEI 22, which may be configured to operate at standard atmospheric pressure. The cassette 10 is also selectively separated from FEI 22 by cassette doors 23. In the FEI 22 are robot arms 24 having end effectors 26. The end effectors 26 comprise one or more substrate supports 28, each capable of holding a wafer 20 for transport. In some embodiments, the end effectors 26 could be a fork, paddle, edge grip, vacuum or Bernoulli wand, as described in U.S. Pat. No. 6,073,366 to Aswad, among other configurations readily apparent to those skilled in the art. U.S. Pat. No. 6,073,366 entitled “Substrate Cooling Systems and Method” is herein incorporated by reference. The end effector 26 of one or both of the robot arms may also have a system for conveying a fluid onto the wafer, as will be explained, in order to cool the wafer while the wafer is being transported. The robot arm 24 is configured to be capable of accessing wafer 20, which is located on the cassette rack 16 through a docking port 14, in combination with an elevator mechanism (not shown) for raising and lowering the robot arm 24 for placing wafers in different slots in the FOUP.

A loadlock chamber 40, preferably a low-capacity loadlock chamber, is also adjoined to the FEI 22, the loadlock chamber 40 being accessed by the robot arm 24 via a gate valve or door 42. The loadlock chamber 40 is located to serve as a selectively closeable passageway between the FEI 22 and a wafer handling chamber 44, with a gate valve or door 42 on each end of the loadlock chamber 40. In some embodiments, the load lock 40 can lead directly to a process chamber. Inside the loadlock chamber 40 is a loadlock rack 46. The loadlock rack 46 is composed of individuals slots (not shown) or shelves, each capable of holding a single wafer.

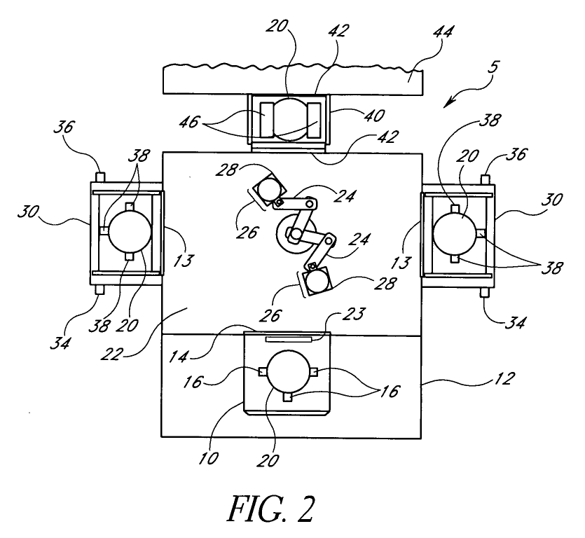

FIG. 2 also shows an overhead plan view of a semiconductor process tool 5 constructed in accordance with some embodiments. In addition to all of the components and systems as described in FIG. 1, FIG. 2 shows that in some embodiments a buffer station 30 may also be provided. The buffer station 30, which is preferably separated from the FEI 22 by buffer station doors 13, preferably has both pump down and purging capabilities facilitated by a purge valve 34 and gas inlet 36. In some embodiment, the buffer station 30 has a reduced pitch buffer station rack 38 interior to the buffer station 30. The buffer station rack 38 is formed from slots (not shown) or shelves, each slot being capable of holding a single wafer 20; however, the reduced pitch buffer station rack 38 has closer relative spacing between the slots as compared with the relative spacing of the slots in the cassette rack 16. The robot arm 24 is further configured to allow access to a buffer station 30.

It should also be understood that in some embodiments of the semiconductor process device, the position which the buffer station occupies is advantageously used for a completely different function. The buffer station may be replaced with a pre-processing station or a post-processing station, with minimal increase in the size of the semiconductor process device footprint. For example, the buffer station may be replaced with a pre-clean station, such as an etch station, or a post-processing station where processes such as annealing of the deposition of other layers, such as a sealing oxide layer, are conducted as explained in U.S. Pat. No. 6,696,367 to Aggarwal et. al., and herein incorporated by reference. In some embodiments, the buffer station may be replaced by a metrology device without the need to substantially change the system configuration.

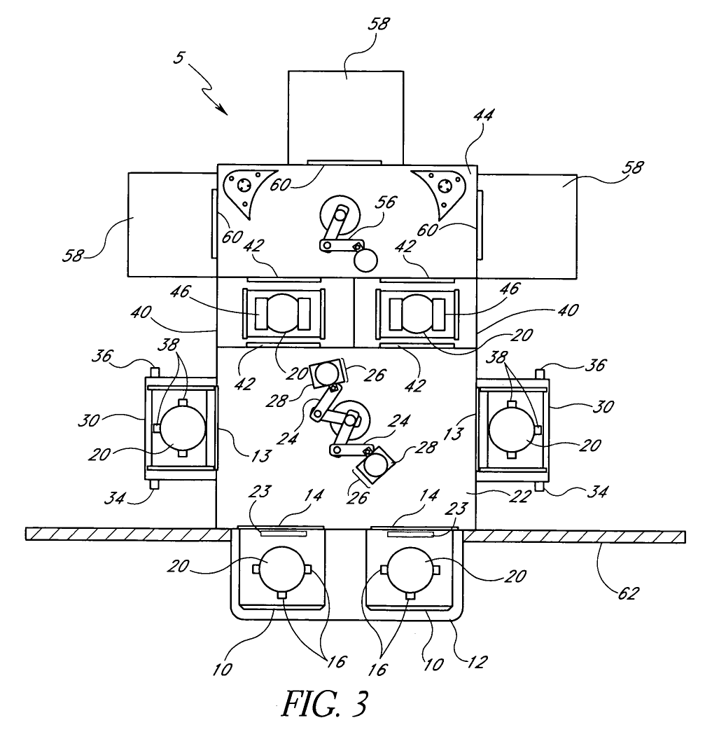

FIG. 3 further illustrates an overhead schematic view of a semiconductor process device 5. In addition to all of the components and systems of FIGS. 1 and 2, FIG. 3 shows a wafer handling chamber 44 and various process chambers 58 in accordance with some embodiments. The illustrated semiconductor process device 5 includes two buffer stations 30 and two load lock chambers 40. Behind the loadlock chambers is a wafer handling chamber 44, in which a wafer handling chamber robot 56 is positioned to have effective access to both the loadlock chambers 40 and the interior of a plurality of individual process chambers 58. In one embodiment, the wafer handling robot 56 has cooling on its end effectors as described herein. The loadlock chambers 40 and the process chambers 58 are also preferably selectively sealable from the wafer handling chamber 44 through the use of gate valves 60 and 42. In some embodiments, a clean room wall 62 defines a “gray room” environment to which wafers are not exposed while the cassettes 10 are located on the clean room side of the wall, which is cleaner. In an alternate embodiment, the clean room wall may be placed closer to the process chambers 58 or completely absent from the fabrication tool setup.

With reference to FIGS. 1-3, the operation of some embodiments shown preferably begins with a cassette 10 of wafers 20 arriving at the docking port 14 of an FEI 22. A robot arm 24 located inside the FEI 22 preferably moves the end effector 26 through the docking port 14 and locates the end effector 26 proximate to a cassette rack 16 contained within the cassette 10. The robot arm 24 then removes a wafer 20 from the cassette rack 16. The robot arm 24 then transfers the wafer 20 to the loadlock chamber 40 and places the wafer on loadlock rack 46. In some embodiments, for instance the embodiment of FIG. 3, the robot arm 24 can initially transfer the wafer 20 to a buffer station 30, as described below.

After the wafer is transferred to loadlock chamber 40, the gate valve or door 42 on the FEI 22 side closes, and the gate valve or door 42 on the wafer handling chamber 44 side opens. The wafer handling robot 56 then transfers the wafer to one of the processing chambers 58 for processing. Before processing begins the gate valve 60 closes, and after processing is ended the gate valve 60 opens to allow the wafer handling robot 56 to transfer the wafer 20 back to a loadlock chamber 40. After the wafer handling robot 56 transfers the wafer to the loadlock chamber 40, the gate valve or door 42 on the wafer handling chamber 44 side closes, and the gate valve or door on the FEI 22 side opens to allow robot arm 24 with cooling system on end effector 26 to access the wafer.

The robot arm 24 with cooling system on end effector 26 then transfers the wafer 20 back to the cassette 10. During the transfer process, the robot arm 24 with cooling system on end effector 26 cools the wafer 20 so that by the time it reaches the cassette 10, the wafer has been cooled so as not to damage the cassette rack 16. In some embodiments as described below and for example the embodiment of FIG. 3, the robot arm with cooling system on end effector 26 transfers the wafer from the loadlock chamber 40 to a buffer station 30. During the transfer process, the robot arm 24 with cooling system on end effector 26 cools the wafer. Buffer station 30 may be used for any number wafer processing or handling processes, including, for example, further cooling of the wafer before it is transferred to the cassette 10. The above described process is then repeated for each wafer that is to be processed.

In some embodiments, for example the embodiments of FIG. 3, after the robot arm 24 removes a wafer 20 from the cassette rack 16, the robot arm 24 places the wafer in a buffer station 30. Preferably, this transfer of the wafer 20 from the cassette rack 16 to the buffer station rack 38 is done immediately upon the docking of the cassette 10 with the front docking port 14. After all of the wafers 20 from the cassette 10 are unloaded into the buffer station 30, the door 13 separating the buffer station from the FEI 22 is closed in order to minimize contamination. In some embodiments, once the wafers 20 are in the buffer station rack 38, the buffer station 30 is then pumped down and purged to create an inert environment in which to store the wafers 20. After unloading a wafer the robot arm 24 returns to the cassette rack 16 for the number of cycles required to transfer all of the wafers 20 from the cassette 10 into the buffer station 30, as described above.

Once the desired number of wafers 20 have been transferred from the cassette rack 16 to the buffer station rack 38, the robot arm 24 unloads wafers 20 from the buffer station rack 38 and places the wafers 20 onto the loadlock rack 46, as needed for processing. Preferably, wafers 20 in need of processing are unloaded in the loadlock rack 46 by the robot arm 24, while those wafers which have already been processed are preferably shuttled back to the buffer station rack 38 on the robot arm's return trip or by a second robot arm 24 with cooling system on end effector 26. In some embodiments, processed wafers are stored in a buffer station 30, while unprocessed wafers are stored in a separate buffer station 30 on the other side of the FEI 22. The robot arm 24 preferably is programmed to continue to cycle between the buffer station 30 and the loadlock 40 until all wafers 20 are processed, before transferring wafers 20 back to the cassette rack 16.

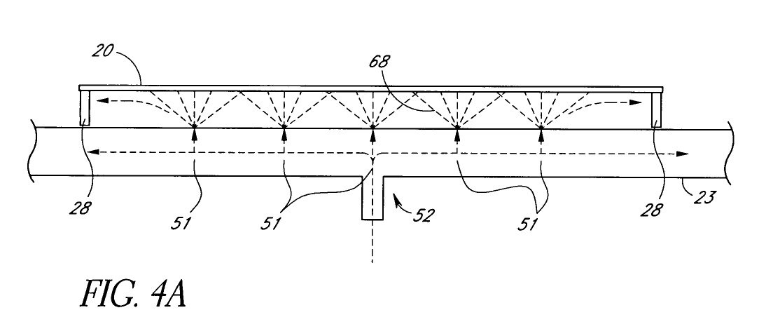

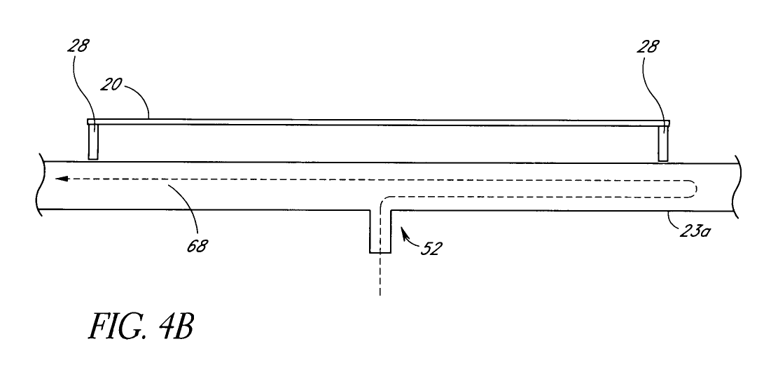

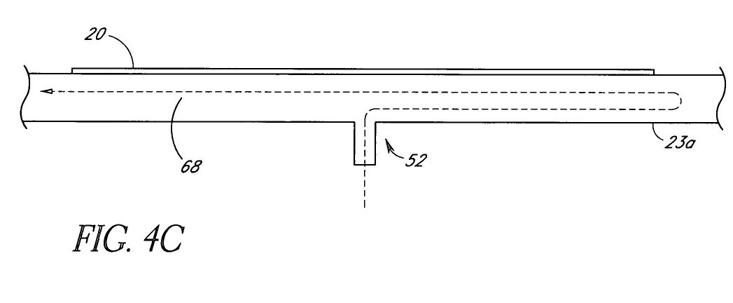

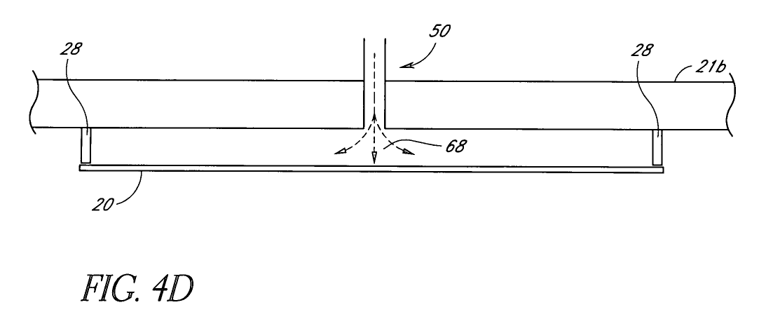

FIG. 4A schematically illustrates some embodiments of the cooling system comprised in the end effector 26 attached to the robot arm 24. The cooling system transports a fluid 68 to the wafer in order to cool the wafer 20 as it is being transported by the robot arm 24. A lower showerhead assembly 23 is located within or adjacent to a lower portion of the end effector 26. Substrate supports 28 are used to support the wafer 20 as it is being transported. In one embodiment, the substrate supports 28 are pads for supporting a wafer 20 on the backside of the wafer 20. In one embodiment, the substrate supports 28 are made from high temperature materials. In one embodiment, the substrate supports 28 contact the wafer in the exclusion zone of wafer 20. In an alternative embodiment, an upper showerhead assembly is located within or adjacent to an upper portion of the end effector 26. Although the addition of an upper showerhead is possible, an upper showerhead may make it difficult to pick up a wafer 20.

Fluid 68 enters the lower showerhead assembly 23 through inlet portion 52. Inlet portion 52 can be simply holes or some other structure for conveying the fluid 68. The fluid 68 flows throughout the interior of lower showerhead assembly 23 and exits through shower spouts 51. The fluid 68 is sprayed onto the wafer 20 in order to cool the wafer 20.

The fluid 68 may be any fluid or gas capable of cooling wafer 20. Inert gases are particularly suited for use in cooling wafers. This is because inert gases are safe and do not cause an adverse reaction on the wafer's 20 surface. In some embodiments, nitrogen gas is the fluid sprayed onto the wafer 20.

FIG. 4B illustrates another embodiment of the end effector 26 cooling system. FIG. 4B illustrates a cooling system utilizing conduction. Fluid 68 is transported into lower cooling portion 23a through inlet portion 52. Again, the fluid 68 cools the wafer 20 through conductive means. A conductive system for cooling wafer 20 may be advantages because a wider variety of fluids may be used to cool the wafer 20 which would otherwise damage the wafer 20 if sprayed directly onto wafer 20 as in the embodiment of FIG. 4A. In an alternative embodiment, an upper conductive cooling portion is provided for cooling wafer 20. However, as discussed above, an upper cooling portion make it difficult to pick up the wafer.

FIG. 4C illustrates schematically a conductive cooling system in which wafer 20 is placed directly onto lower cooling portion 23a. This embodiment may be advantageous because it allows for greater contact between the lower cooling portion 23a and the wafer 20. Such a configuration would allow for greater dissipation of heat because there is direct physical contact between the lower cooling portion 23a and the wafer 20.

FIG. 4D illustrates a cooling system combined with a Bernoulli wand system for transporting the wafers. As explained in U.S. Pat. No. 6,073,366 to Aswad, the jets 50a used to transport a wafer 20 by a Bernoulli wand may be modified to incorporat a cooling system. The jets may be modified to use a cooling fluid 68 in order to both lift, and cool the wafer at the same time. Also illustrated FIG. 4E are upper jet support portion 21b as well as substrate support 28.

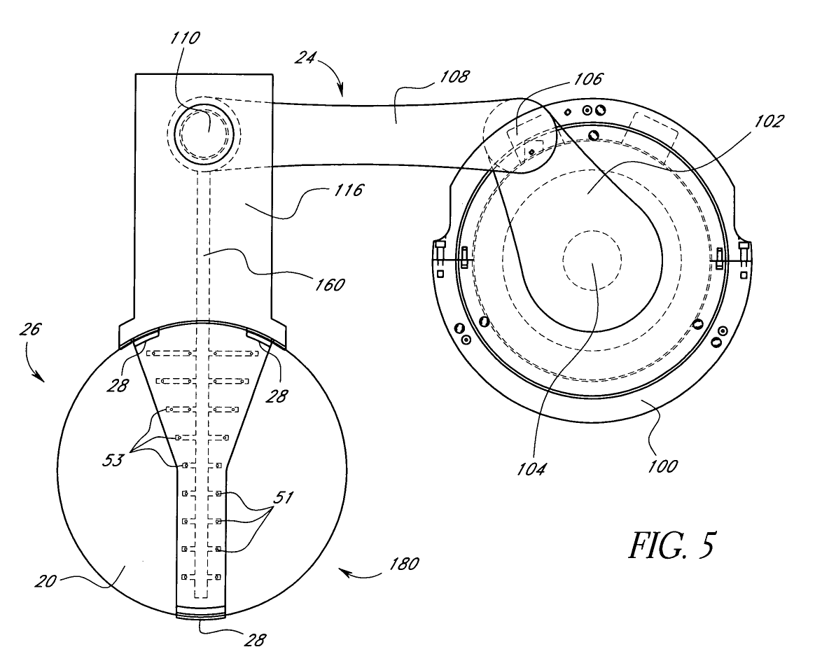

FIG. 5 schematically represents robot arm 24 with end effector 26 and substrate supports 28. As can be seen in FIG. 5, robot arm 24 is connected to base 100 and comprises a system of supports and joints which are capable of moving relative to one another. Any wafer transport robot may be used with embodiments of the present invention, and the robot arm illustrated in FIG. 5 is only an example of one possible robot arm. In the embodiment illustrated in FIG. 5, fluid is transported to the wafer through fluid lines extending through the supports and joints to the end effector cooling system. In an alternative embodiment, the fluid can be transported to the end effector through external lines which are then connected to the end effector near the mounting of the end effector.

As illustrated in FIG. 5, robot arm 24 is mounted onto the floor by robot arm base 100. The robot arm 24 could also be mounted onto a wall or onto the ceiling, or any other suitable surface. Robot arm base 100 is generally frustoconical in shape. The larger diameter end of robot arm base 100 is mounted to the floor and the smaller diameter end is moveably connected to the robot arm support piece 102. Robot arm base 100 is movably connected to robot arm support piece 102 through robot arm base joint 104. The robot arm base joint 104 allows the robot arm support piece 102 to move relative to robot arm base 100. The movement can be a swivel motion, or a vertical or horizontal movement and can be designed in any manner known to those in the art.

Robot arm support piece 102 is shaped so that it is thickest where it connects with the robot arm base 100 and then thins as it gets closer to where it connects with the robot arm joint 106. Robot arm support piece 102 is moveably connected to robot arm support piece 108 by means of robot arm joint 106. The robot arm joint 106 allows the robot arm support pieces 108 and 102 to swivel relative to one another. In addition to a swivel motion, the motion could be a horizontal or vertical movement depending on the type of joint used.

Robot arm support piece 108 is generally rectangular with rounded edges. Robot arm support piece 108 is movably connected to end effector support piece 116 by means of robot arm joint 114. Robot arm joint 114 allows robot arm support piece 108 and end effector support piece 116 to swivel relative to one another. In addition to a swivel motion, the motion could be a horizontal or vertical movement depending on the type of joint used.

End effector support piece 116 is rectangular on one side, and is rounded on the other side so as to connect with the end effector 26. End effector support piece 116 is connected to the end effector 26 which contains the end effector cooling system 180.

Fluid may be routed through fluid line 160 to the wafer cooling system 180. Fluid line 160 may be routed through the base 100 and supports and joints 102, 104, 106, 108, 110, 112, and 114, or fluid line 160 may be routed outside of the robot arm before it enters end effector support piece 116. Fluid line 160 is then routed through the end effector in a fluid branch system. The fluid line 160 routs fluid to the shower spouts 51 which spray the wafer 20. In the embodiment of FIG. 5, the shower spouts are located below the wafer 20, and thus spray the fluid on the underside of the wafer 20. FIG. 5 shows a system of 24 showers spouts 51; however, more or fewer shower spouts 51 may be used. The shower spouts 51 can be connected to the branches of fluid line 160. One or more branches 53 can extend transverse to the fluid line 160. As illustrated, 9 branches extend transverse to the fluid line 160 on each side. Branches 53 may have one or more spouts 51 on each side of the fluid line 160. As illustrated, three branches 53 have two spouts 51 included on each side and 6 branches have at least one spout 51 included on each side.

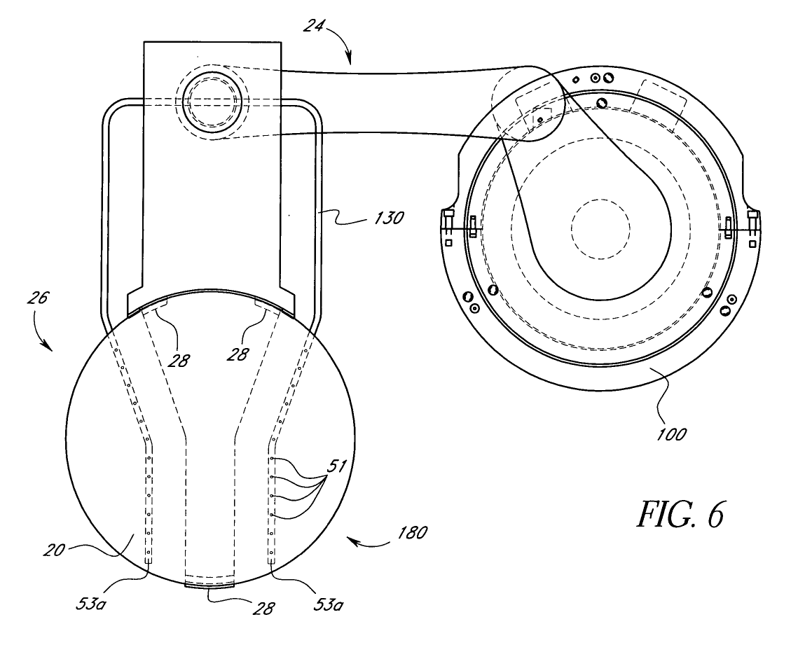

FIG. 6 schematically represents another embodiment of the robot arm 24 with wafer cooling system 180. In addition to the base, supports, and joints as described in FIG. 5, FIG. 6 shows how a fluid 68 is transported to the end effector cooling system 180 by means of external fluid lines 130 which are routed through robot arm 24. The fluid is then sprayed onto wafer 20 through shower spouts 51 provided in series a opposite sides of the end effector. In this embodiment, the shower spouts 51 are mounted on fluid lines 130. FIG. 6 shows an embodiment of 24 shower spouts; however, more or fewer shower spouts may be used in this embodiment of the invention. For example, one or more, six or more, or even eight or more spouts may be provided on each side of the end effector.

Although the foregoing invention has been described in terms of certain preferred embodiments, other embodiments will be apparent to those of ordinary skill in the art from the disclosure herein. For instance, any advantages configuration for transporting fluid to the end effector may be used.

What is claimed is:

1. A semiconductor processing device, comprising:
a wafer handling section connected to a first side of a loadlock chamber and including a wafer handling robot;
a processing chamber communicating with the wafer handling section;
a front end interface connected to a second side of the loadlock chamber and including a cassette rack;
an interface robot located within the front end interface, supporting an end effector, the interface robot configured to supply a fluid to a wafer held by the end effector.

2. The semiconductor processing device of claim 1, wherein the interface robot is configured to remove heat convectively from the wafer by supplying the fluid.

3. The semiconductor processing device of claim 2, wherein the fluid is nitrogen gas.

4. The semiconductor processing device of claim 2, wherein the interface robot is configured to spray the fluid onto the wafer.

5. The semiconductor processing device of claim 4, wherein the fluid is nitrogen gas.

6. The semiconductor processing device of claim 1, wherein the wafer handling section is an enclosed chamber.

7. A semiconductor processing device, comprising:
a loadlock chamber;
a front end interface connected to the loadlock chamber;
a cassette rack in communication with the front end interface;
an interface robot located within the front end interface for transporting semiconductor wafers between the loadlock chamber and the cassette rack, the interface robot containing an end effector for holding a wafer, the interface robot further comprising a fluid showerhead connected to a source of fluid to enable fluid to pass through openings in the showerhead onto a surface of a wafer.

8. The semiconductor processing device of claim 7, wherein the fluid is an inert gas.

9. The semiconductor processing device of claim 8, wherein the inert gas is nitrogen gas.

10. A semiconductor processing device, comprising:
a front end interface connected to a loadlock chamber, the front end interface configured to receive semiconductor wafers in a cassette unit; and
a robot located within the front end interface capable of transporting wafers between the loadlock chamber and the cassette unit, the robot comprising an end effector for holding a wafer;
the end effector being configured to transfer a cooling fluid to the wafer.

11. The semiconductor processing device of claim 10, wherein the end effector transfers fluid to the wafer through spraying.

12. The semiconductor processing device of claim 11, wherein the fluid is nitrogen gas.

13. The semiconductor processing device of claim 10, further comprising
a processing chamber;
a wafer handling chamber connected to the processing chamber, the wafer handling chamber in communication with the loadlock chamber, the wafer handling chamber comprising a wafer handling robot configured to transport wafers from the processing chamber to the loadlock chamber.

14. A semiconductor processing device, comprising:
a front end interface connected to a loadlock chamber, the front end interface configured to receive semiconductor wafers in a cassette unit;
a robot located within the front end interface containing an end effector for transporting wafers from the loadlock chamber to the cassette unit, the end effector comprising passages through which cooling fluid is circulated, the end effector being configured to have a lower surface temperature after the cooling fluid is circulated through the end effector as compared to the surface temperature of the end effector prior to circulating the cooling fluid through the end effector.

15. The semiconductor processing device of claim 14, wherein the cooling fluid is nitrogen gas.

16. A method for cooling a processed semiconductor wafer, comprising:
moving a processed wafer from a loadlock chamber to an end effector of an interface robot;
supplying a cooling fluid from the interface robot to the processed wafer;
cooling the processed wafer to at least 70 degrees Celsius from a temperature above 71 degrees Celsius; and
transporting the cooled wafer to a cassette rack with the interface robot.

17. The method of claim 16, wherein the cooling fluid is nitrogen gas.

18. The method of claim 16, further comprising processing a wafer at a temperature over 500 degrees Celsius prior to moving the processed wafer from the loadlock chamber to the end effector of the interface robot.

19. The method of claim 16 further comprising placing a wafer in a cooling station in a wafer handling device prior to moving the processed wafer from the loadlock chamber to the end effector of the interface robot.

20. The method of claim 16 wherein the starting temperature of the wafer while in the loadlock chamber and prior to moving into the wafer handling chamber is below 70 degrees Celsius.
